(19) United States
(12) Patent Application Publication
(10) Pub. No.: US 2013/0135795 A1
(43) Pub. Date: May 30, 2013

(54) ELECTRONIC DEVICE

(71) Applicants: Weng-Chang Shen, Taoyuan County (TW); Chih-Kuang Wang, Taoyuan County (TW)

(72) Inventors: Weng-Chang Shen, Taoyuan County (TW); Chih-Kuang Wang, Taoyuan County (TW)

(73) Assignee: HTC CORPORATION, Taoyuan County (TW)

(21) Appl. No.: 13/307,001

(22) Filed: Nov. 30, 2011

(51) Int. Cl. H05K 7/00

(52) U.S. Cl. 361/679.01

(57) ABSTRACT

An electronic device including a casing and a display module is provided. The casing has an opening. The display module is disposed in the casing and includes a backlight module and a display panel. The display panel is disposed on the backlight module and located between the backlight module and the opening. The display panel entirely covers the backlight module, and the periphery of the display panel is adjacent to the casing.

### BACKGROUND OF THE INVENTION

1. Field of the Invention

The present application relates to an electronic device, and more particularly, to an electronic device having a display module.

2. Description of Related Art

A handheld electronic device refers to an electronic device which can be held and operated in a user's hand, such as mobile phone, multimedia player, personal digital assistant (PDA), pocket PC, handheld game console, and handheld global positioning system (GPS). These electronic devices usually have small volume and light weight, so that they can be carried around with ease.

The conventional handheld electronic devices commonly use flat display modules to display images, wherein among the various flat display modules, a liquid crystal display is more mature and more popularized. However, a liquid crystal panel of the liquid crystal display does not emit light by itself. Therefore, a backlight module acting as a light source is disposed below the liquid crystal display panel to achieve the displaying function. In general, a housing including a back plate and a mold frame is mostly used in the backlight module to fix the components like light source, and at the same time the housing also supports and covers the display panel. However, if the display panel is covered by using the housing of the backlight module, the housing may extend to reach the place located between the periphery of the display panel and the casing. And it may increase the frame width of the periphery of the display panel of the handheld electronic device, and thus the demand of a narrow frame design of the handheld electronic device cannot be met.

### SUMMARY OF THE INVENTION

The present application provides an electronic device capable to reach the demand of a narrow frame design.

The present application provides an electronic device which includes a casing and a display module. The casing has an opening. The display module is disposed in the casing and includes a backlight module and a display panel. The display panel is disposed on the backlight module and located between the backlight module and the opening. The display panel entirely covers the backlight module, and a periphery of the display panel is adjacent to the casing.

In light of the above, in the present application, the display panel entirely covers the backlight module, and the periphery of the display panel is adjacent to the casing and thus the display panel is protected by the casing. Accordingly, the backlight module does not extend to the place which is between the periphery of the display panel and the casing, and it may reduce the frame width of the display panel of the electronic device, and the demand of a narrow frame design can further be achieved.

Several exemplary embodiments accompanied with figures are described in detail below to further describe the invention in details.

### BRIEF DESCRIPTION OF THE DRAWINGS

The accompanying drawings constituting a part of this specification are incorporated herein to provide a further understanding of the invention. Here, the drawings illustrate embodiments of the invention and, together with the description, serve to explain the principles of the invention.

FIG. 1 is a schematic three-dimensional view illustrating an electronic device according to an embodiment of the present invention.

FIG. 2 is a cross-sectional view of the electronic device depicted in FIG. 1 along a sectional line A-A.

FIG. 3 is a schematic view of the display module of FIG. 2.

FIG. 4 is a schematic three-dimensional view of the casing of FIG. 1.

FIG. 5A is a partial cross-sectional view of the first hole of the electronic device of FIG. 1.

FIG. 5B is a partial cross-sectional view of the second hole of the electronic device of FIG. 1.

FIG. 6 is a cross-sectional view of the electronic device depicted in FIG. 1 along a sectional line B-B.

### DESCRIPTION OF EMBODIMENTS

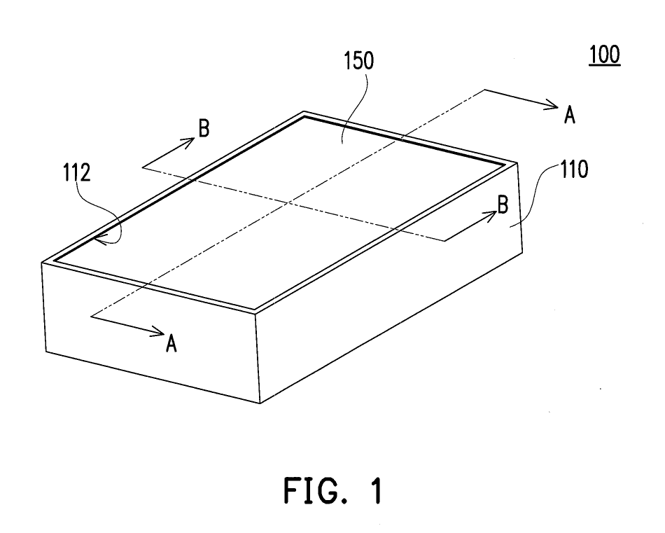

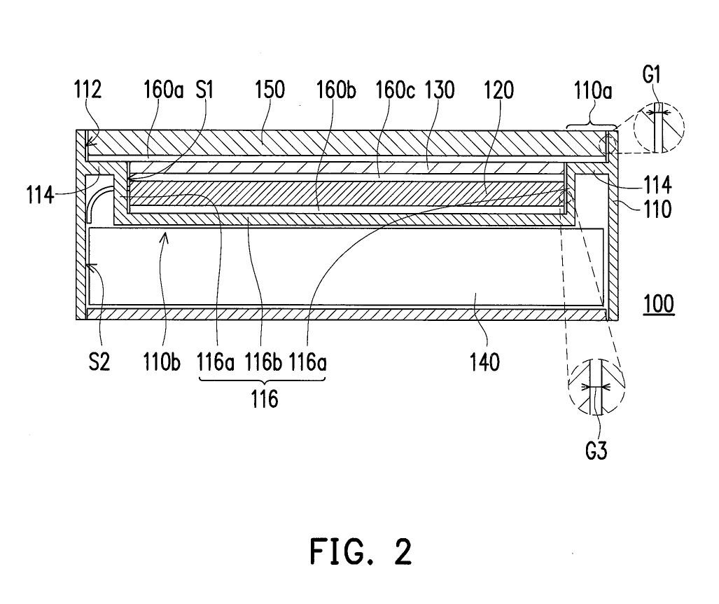

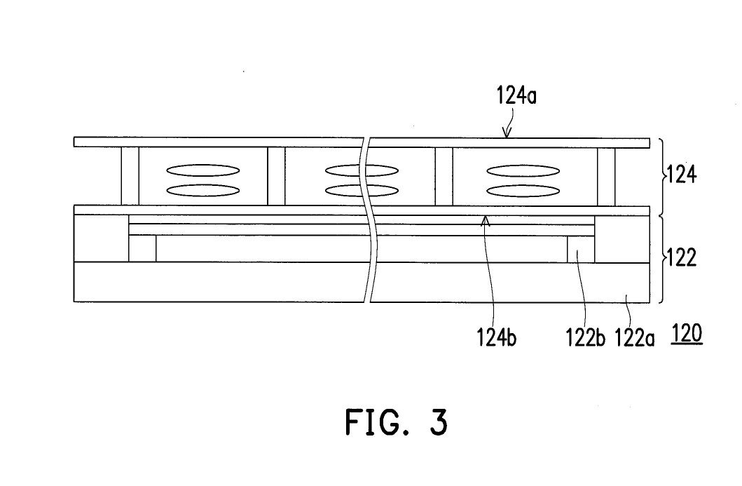

FIG. 1 is a schematic three-dimensional view illustrating an electronic device according to an embodiment of the present invention. FIG. 2 is a cross-sectional view of the electronic device depicted in FIG. 1 along a sectional line A-A. FIG. 3 is a schematic view of the display module of FIG. 2. Please refer to FIG. 1 to FIG. 3, the electronic device of the present embodiment is, for example, a mobile phone, a multimedia player, a handheld game console, a handheld global positioning system (GPS) and a tablet PC. The electronic device 100 includes a casing 110 and a display module 120. The casing 110 has an opening 112. The display module 120 is disposed in the casing 110 and includes a backlight module 122 and a display panel 124. The display panel 124 is disposed on the backlight module 122 and located between the backlight module 122 and the opening 112. The backlight module 122 provides lights for the display panel 124 to display images. The user can view the image displayed by the display panel 124 through the opening 112.

In the present embodiment, the display panel 124 entirely covers the backlight module 122, and the periphery of the display panel 124 is adjacent to the casing 110 and thus the display panel 124 is protected by the casing 110. Accordingly, the backlight module 122 may not extend to the place which is between the periphery of the display panel 124 and the casing 110, and it may reduce the width of the frame 110a of the periphery of the display panel 124 of the electronic device 100, and thus the demand of a narrow frame design can further be achieved.

Referring to FIG. 3, more specifically, the backlight module 122 described in this embodiment includes a housing 122a and at least one light source 122b (two light sources are shown in the figure). The display panel 124 has a display surface 124a and a back surface 124b opposing to the display surface 124a. The display surface 124a faces toward the opening 112, and the housing 122a is fixed at the back surface 124b. The light sources 122b are disposed at the housing 122a and face toward the back surface 124b of the display panel 124, in order to provide lights to the display panel 124 for displaying images. The housing 122a of the backlight module 122 just supports the display panel 124 and does not cover the periphery of the display panel 124, so that the periphery of the display panel 124 can be adjacent to the casing 110 shown in FIG. 2, and it advantages the narrow frame design.

Referring to FIG. 2 and FIG. 3, in this embodiment, the electronic device 100 further includes a touch panel 130. The touch panel 130 is disposed on the display panel 124 and located between the display panel 124 and the opening 112. In other embodiments, the electronic device 100 can also be any other type of electronic device without a touch panel.

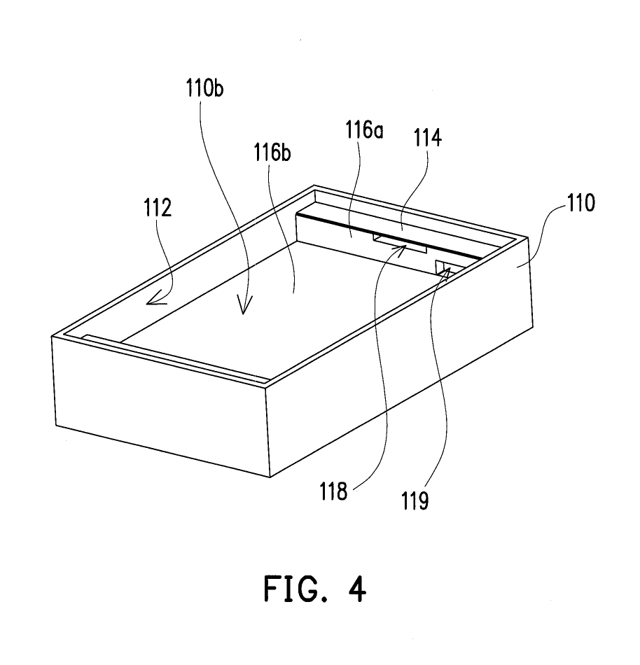

FIG. 4 is a schematic three-dimensional view of the casing of FIG. 1. Referring to FIG. 2 and FIG. 4, in this embodiment, the electronic device 100 further includes a circuit board 140. The casing 110 has a stopping wall 110b disposed therein. The stopping wall 110b separates the inside of the casing 110 into a first space S1 and a second space S2. The first space S1 is connected to the opening 112 and located between the second space S2 and the opening 112. The display module 120 is disposed in the first space S1, and the circuit board 140 is disposed in the second space S2.

The stopping wall 110b in this embodiment includes two connecting portions 114 and a carrying portion 116. The two connecting portions 114 respectively extend from two opposite inner walls of the casing 110. The carrying portion 116 is connected between the two connecting portions 114. The display module 120 is carried on the carrying portion 116. The electronic device 100 further includes a transparent cover 150 and an adhesive layer 160a. The transparent cover 150 is disposed at the opening 112 and covers the display module 120. Two opposite ends of the transparent cover 150 extend from a periphery of the display module 120, leaning on the two connecting portions 114 and adhered to the two connecting portions 114 through the adhesive layer 160a, respectively.

More specifically, the carrying portion 116 includes two sidewalls 116a and a bottom plate 116b. The two sidewalls 116a are respectively connected to the two connecting portions 114, and the bottom plate 116b is connected between the two sidewalls 116a. The display module 120 is carried on the bottom plate 116b and restricted between the two sidewalls 116a, so that the whole structure can be firmly fixed.

Referring to FIG. 2, in this embodiment, the electronic device 100 further includes adhesive layers 160b and 160c. The display module 120 is adhered to the stopping wall 110b through the adhesive layer 160b, and the touch panel 130 is adhered to the display module 120 through the adhesive layer 160c.

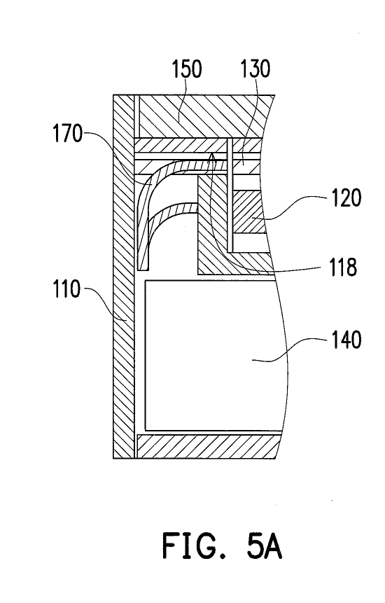

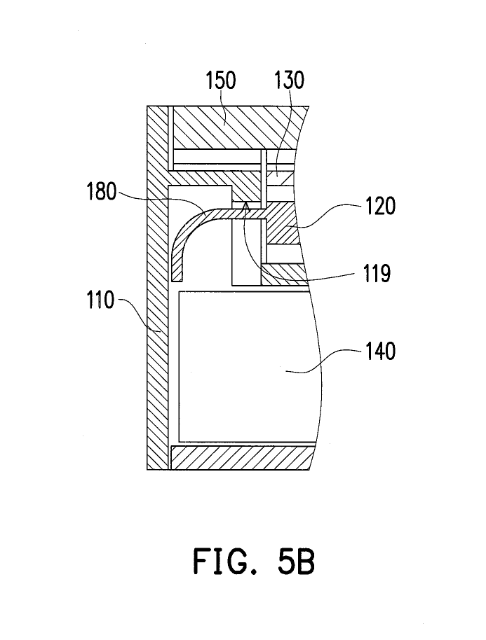

FIG. 5A is a partial cross-sectional view of the first hole of the electronic device of FIG. 1. FIG. 5B is a partial cross-sectional view of the second hole of the electronic device of FIG. 1. Referring to FIG. 4, FIG. 5A and FIG. 5B, in this embodiment, the stopping wall 110b has a first hole 118. A conducting wire 170 is connected between the touch panel 130 and the circuit board 140 through the first hole 118, so as to advantage the electrical conduction between the touch panel 130 and the circuit board 140. In addition, the stopping wall 110b further has a second hole 119. A conducting wire 180 is connected between the display panel 120 and the circuit board 140 through the second hole 119, so as to advantage the electrical conduction between the display panel 120 and the circuit board 140.

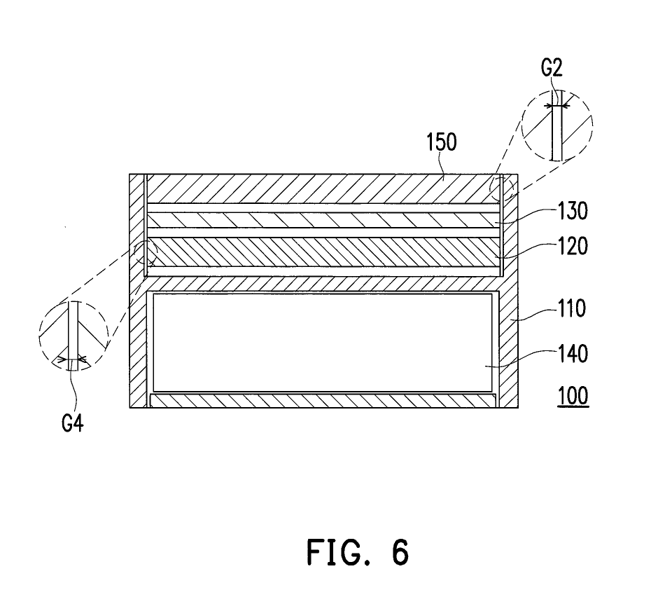

FIG. 6 is a cross-sectional view of the electronic device depicted in FIG. 1 along a sectional line B-B. Referring to FIG. 2 and FIG. 6, in this embodiment, gaps G1 and G2 are formed between the periphery of the transparent cover 150 and the casing 110, and gaps G3 and G4 are formed between the periphery of the display module 120 and the casing 110. Therefore, the impact force exerted to the transparent cover 150 and the display module 120 of the electronic device 100 can be reduced, and the probability of the damage of the electronic device 100 due to accidentally falling or dash can further be reduced.

In light of the foregoing, in the present application, the display panel entirely covers the backlight module, and the periphery of the display panel is adjacent to the casing and thus the display panel is protected by the casing. Accordingly, the backlight module does not extend to the place which is between the periphery of the display panel and the casing, and it may reduce the frame width of the display panel of the electronic device, and the demand of a narrow frame design can further be achieved.

It will be apparent to those skilled in the art that various modifications and variations can be made to the structure of the disclosure without departing from the scope or spirit of the invention. In view of the foregoing, it is intended that the disclosure cover modifications and variations of this invention provided they fall within the scope of the following claims and their equivalents.

What is claimed is:

1. An electronic device, comprising:
a casing having an opening; and
a display module disposed in the casing and comprising:
a backlight module; and
a display panel disposed on the backlight module and located between the backlight module and the opening, wherein the display panel entirely covers the backlight module, a periphery of the display panel is adjacent to the casing.

2. The electronic device as claimed in claim 1, wherein the backlight module comprises:
a housing, the display panel having a display surface and a back surface opposing to the display surface, the display surface facing toward the opening, the housing fixed at the back surface; and
at least one light source disposed at the housing and facing toward the back surface.

3. The electronic device as claimed in claim 1, further comprising a touch panel, wherein the touch panel is disposed on the display panel and located between the display panel and the opening.

4. The electronic device as claimed in claim 1, further comprising a circuit board, wherein the casing has a stopping wall disposed therein, the stopping wall separates the inside of the casing into a first space and a second space, the first space is connected to the opening and located between the second space and the opening, the display module is disposed in the first space, the circuit board is disposed in the second space.

5. The electronic device as claimed in claim 4, wherein the stopping wall has at least one hole, at least one conducting wire is connected between the display module and the circuit board through the at least one hole.

6. The electronic device as claimed in claim 4, further comprising a transparent cover disposed at the opening and covering the display module, wherein the stopping wall comprises two connecting portions and a carrying portion, the two connecting portions respectively extend from two opposite inner walls of the casing, the carrying portion is connected between the two connecting portions, the display module is carried on the carrying portion, two opposite ends of the transparent cover extend from a periphery of the display module and leaning on the two connecting portions respectively.

7. The electronic device as claimed in claim 6, further comprising an adhesive layer, wherein the transparent cover is adhered to the two connecting portions through the adhesive layer.

8. The electronic device as claimed in claim 6, wherein the carrying portion comprises:
two sidewalls respectively connected to the two connecting portions; and
a bottom plate connected between the two sidewalls, wherein the display module is carried on the bottom plate and restricted between the two sidewalls.

9. The electronic device as claimed in claim 6, wherein a gap is formed between a periphery of the transparent cover and the casing.

10. The electronic device as claimed in claim 1, wherein a gap is formed between a periphery of the display module and the casing.
